(19) United States
(12) Patent Application Publication
(10) Pub. No.: US 2025/0044491 A1
(43) Pub. Date: Feb. 6, 2025

(54) SEMICONDUCTOR CHIP AND METHOD OF PRODUCING A PLURALITY OF SEMICONDUCTOR CHIPS

(71) Applicants: ams-OSRAM AG, Premstaetten (AT); ams-OSRAM International GmbH, Regensburg (DE)

(72) Inventors: Laura KREINER, Regensburg (DE); Fredrik PRINCE, Graz (AT)

(21) Appl. No.: 18/846,663

(22) PCT Filed: Mar. 13, 2023
(86) PCT No.: PCT/EP2023/056306

§ 371 Date: Sep. 13, 2024

(30) Foreign Application Priority Data
Mar. 17, 2022 (DE) 10 2022 106 254.6

(51) Int. Cl. G02B 5/28; H01L 33/02

(52) U.S. Cl. CPC G02B 5/281; H01L 33/02

(57) ABSTRACT

A semiconductor chip comprising a semiconductor layer sequence with an active region. The active region is configured to generate radiation. The semiconductor chip further includes a filter layer sequence wherein at least one first layer of the filter layer sequence comprises amorphous silicon. Further, a method of producing a plurality of semiconductor chips is disclosed.

### RELATED APPLICATIONS

This application is a National Stage application, filed under 35 U.S.C. § 371, of International Patent Application No. PCT/EP2023/056306, filed on Mar. 13, 2023, and claims priority under 35 U.S.C. § 119 (a) and 35 U.S.C. § 365 (b) from German Patent Application No. 10 2022 106 254.6, filed Mar. 17, 2022; the above applications are incorporated by reference herein in their entirety.

### FIELD

The present application relates to a semiconductor chip and to a method of producing semiconductor chips.

### BACKGROUND

The emission wavelength of light-emitting diodes, in short LEDs, emitting in the red or infrared spectral range typically shifts with the temperature. This effect is due to the material properties of the semiconductor material used and can hardly be reduced by additional measures. For devices that use such LEDs in combination with dielectric filters arranged downstream of the LEDs, this effect may cause the radiation characteristics to vary, not only with respect to the wavelength but also with respect to the spatial emission characteristics. For example, the shape of the far field of the LED may vary with the temperature. In addition, LEDs emitting in the infrared spectral range may also emit some undesired radiation that can be perceived by the human eye. This effect is also referred to as red glow.

### SUMMARY

At least one embodiment of the present disclosure relates to a semiconductor chip with improved radiation characteristics. Furthermore, at least one embodiment of the present disclosure relates to a method that allows for a simple and reliable production of semiconductor chips.

According to at least one embodiment of the semiconductor chip, the semiconductor chip comprises a semiconductor layer sequence with an active region configured to generate radiation. For example, the active region is configured to emit radiation in the visible spectral range or in the infrared spectral range. For example, the semiconductor chip is configured to emit incoherent radiation.

For example, the semiconductor layer sequence is based on a compound semiconductor material system such as an arsenide or phosphide compound semiconductor material.

Based on arsenide or phosphide compound semiconductor material means in the present context that the semiconductor layer sequence or at least a part thereof, such as, for example, at least the active region and/or the growth substrate, has a compound semiconductor material with arsenic and/or phosphorus as group V element, having AlₓIn_{y}Ga_{1-x-y}P_{z}As_{1-z} or consisting thereof, where 0≤x≤1, 0≤y≤1, x+y≤1 and 0≤z≤1. This material does not necessarily have to have a mathematically exact composition according to the above formula. Rather, it may have, for example, one or more dopants as well as additional constituents. For the sake of simplicity, however, the above formula includes only certain constituents of the crystal lattice (Al, Ga, In, P, As), even if these may be partially replaced and/or supplemented by small amounts of other substances.

According to at least one embodiment, the semiconductor chip comprises a filter layer sequence. For example, the filter layer sequence comprises an alternating sequence of first layers and second layers wherein the first and second layers differ from one another with respect to the refractive index. For example, the filter layer sequence comprises at least two layers or at least five layers and/or at most 200 layers or 100 layers or 50 layers.

In other words, the first layers may represent high refractive index layers and the second layers may represent low refractive index layers in an interference filter system.

The second layers may differ from one another, for example, with respect to the material and/or the layer thickness. Likewise, the first layers may differ from one another, for example, with respect to the material and/or the layer thickness.

According to at least one embodiment of the semiconductor chip, at least one first layer of the filter layer sequence comprises amorphous silicon. The filter layer sequence may comprise one or more than one first layer comprising amorphous silicon. Thus, unlike in conventional interference filter systems based on a sequence of dielectric layers, the filter layer sequence comprises at least one layer based on a semiconductor material.

In at least one embodiment, the semiconductor chip comprises a semiconductor layer sequence with an active region configured to generate radiation and further comprises a filter layer sequence wherein at least one first layer of the filter layer sequence comprises amorphous silicon.

It has turned out that amorphous silicon is particularly suited as material in a filter layer sequence. In particular such a filter layer sequence can be configured such that the temperature shift of the transmission characteristics of the filter layer sequence is comparable to the wavelength shift of the generated radiation during operation of the semiconductor chip. For example, first layers comprising amorphous silicon can be combined with dielectric second layers of the filter layer sequence to an interference filter with superior properties, for example with a comparably low temperature-induced change of the spectral and/or angular radiation characteristics.

According to at least one embodiment of the semiconductor chip, the amorphous silicon is hydrogenated at least in regions. Hydrogenated amorphous silicon is also referred to as a-Si:H. In hydrogenated amorphous silicon the dangling bonds of the silicon caused by the non-crystalline structure are saturated by hydrogen atoms.

Hydrogenated amorphous silicon has a refractive index of about 3.5 in the infrared spectral range which is significantly larger than the refractive index of not hydrogenated amorphous silicon which is around 3. The filter layer sequence may also comprise at least one first layer of hydrogenated amorphous silicon and at least one layer of non-hydrogenated silicon.

In particular, it has been found that using amorphous silicon the angular emission characteristics can be improved. At an angle of incidence θ, the wavelength λ(θ) is given by λ(θ)=λ₀(1−(Ne/N⁺)² sin² (θ))^{1/2}. Here, λ₀ is the wavelength at normal incidence, Ne is the refractive index of the external medium, N⁺ is the effective refractive index of the filter layer sequence. Consequently, by increasing the effective refractive index, the angular dependency of the filter layer sequence is reduced. Thus, using amorphous silicon, for example hydrogenated amorphous silicon or non-hydrogenated amorphous silicon, helps to reduce the angular dependency due to the higher refractive index compared to conventionally used dielectric materials.

According to at least one embodiment of the semiconductor chip, the filter layer sequence comprises at least one second layer comprising a dielectric material.

For example, the second layer comprises an oxide such as silicon oxide (SiO₂), Nb₂O₅, Al₂O₃, HfO₂ or Ta₂O₅.

According to at least one embodiment of the semiconductor chip, a refractive index of the second layer is smaller than a refractive index of the first layer. For example, the refractive index of the second layer is at most 3.

In other words, the first layers comprising amorphous silicon may act as high refractive index layers and the second layers may act as low refractive index layers in an interference filter system. The second layers may differ from one another, for example, with respect to the material and/or the layer thickness. Likewise, the first layers may differ from one another.

According to at least one embodiment of the semiconductor chip, the active region is configured to emit radiation with a peak wavelength in the near infrared range. In particular the peak wavelength is at least 800 nm or at least 850 nm or at least 900 nm and/or at most 1500 nm or at most 1200 nm or at most 1000 nm.

Such peak wavelengths can be used for example in sensing application, for example in biometric sensing applications such as face recognition or in-cabin monitoring, for instance.

According to at least one embodiment of the semiconductor chip, the filter layer sequence is configured to block radiation in the visible range, in particular in the red spectral range. For example, the radiation in the visible spectral range is absorbed by the at least one first layer. If the peak wavelength of the radiation emitted by the active region is in the near infrared range for instance, the short wavelength tail of the emitted radiation may be perceived by the human eye, which is not desired in many applications. As these wavelengths are blocked by the filter layer sequence arranged on the semiconductor layer sequence, it is not necessary to provide an additional filter arranged downstream of the LED in order to avoid this red glow. This facilitates the production of compact devices.

According to at least one embodiment of the semiconductor chip, the filter layer sequence is configured as an angle-selective filter. The angle-dependent transmission characteristics can be tuned by the layer thicknesses and the materials used for the first and second layers of the filter layer sequence. For example, the filter layer sequence is configured to transmit radiation with an angle with respect to perpendicular emission of at most 45° or at most 30° or at most 15°, whereas it blocks radiation with larger angles. In this context, perpendicular emission means that the emission runs perpendicular with respect to a plane of main extension of the semiconductor layers of the semiconductor layer sequence. Radiation emitted at larger angles may be reflected back into the semiconductor layer sequence and at least partly re-emitted by the active region as radiation with a smaller emission angle. This effect is also referred to as photon recycling.

According to at least one embodiment of the semiconductor chip, the filter layer sequence is configured as a bandpass filter. The spectral transmission characteristics can be tuned by the layer thicknesses and the materials used for the first and second layers of the filter layer sequence. The width of the spectral transmission may be smaller or broader than the width of the radiation emitted by the active region. For example, the emission spectrum of the active region may be narrowed using the bandpass filter so that a laser-like spectral emission characteristics can be obtained.

According to at least one embodiment of the semiconductor chip, the filter layer sequence is deposited on the semiconductor layer sequence. Thus, a connection layer such as an adhesive layer between the semiconductor chip and the filter layer sequence can be dispensed with. A negative impact of such an adhesive layer for example due to absorption or reduced optical coupling between the semiconductor layer sequence and the filter layer sequence can be avoided.

Furthermore, there is no gas-filled or evacuated space between the semiconductor layer sequence and the filter layer sequence. This helps to improve the optical coupling between the semiconductor chip and the filter layer sequence compared to a conventional design using a separate filter that is spaced apart from the semiconductor chip.

In particular, the filter layer sequence is not produced on a separate substrate and attached to the semiconductor chip or a housing of the semiconductor chip afterwards. Rather, during production of the semiconductor chip, the layers of the filter layer sequence are deposited while the semiconductor chip is still present in a semiconductor chip assembly. For example, the filter layer sequence is deposited on a carrier of the semiconductor layer sequence including the active region. The carrier may be a growth substrate or a carrier that is different from the growth substrate. The carrier, in particular a side face thereof may have traces that are characteristic of a singulation process such as sawing traces or traces of a singulation process using coherent radiation.

In other words, the filter layer sequence is provided on wafer level during production of the semiconductor chips.

Such a filter layer sequence allows a more compact design to be obtained. In particular the direct integration on the carrier of the semiconductor chip does not have any negative impact on the LED form factor.

Furthermore, the temperature differences between the active region and the filter layer sequence during operation are smaller compared to prior art solutions where the filter layers are provided on a separate substrate and attached to the semiconductor chip afterwards.

The semiconductor chip with the filter layer sequence is particularly suited to provide temperature stable emission characteristics with improved directionality and a suppression of red glow at the same time. However, embodiments of the present disclosure is not limited to emission in the infrared spectral range. Rather, the principle may also be applied to other LEDs that do not emit in the infrared spectral range, for instance in the visible range, for example, in order to reduce the width of the emission spectrum.

For example, the semiconductor chip may be used in driver's assistance systems, as light source for cameras such as IP (Internet Protocol) security cameras or night vision cameras, for biometric applications or other monitoring or recognition systems. Eye discomfort due to red glow may be avoided or at least reduced.

Furthermore, a method of producing a plurality of semiconductor chips is specified. For example, the method can be used to produce a semiconductor chip as specified above. Therefore, features disclosed in connection with the semiconductor chip may also apply for the method and vice versa.

In at least one embodiment of the method of producing a plurality of semiconductor chips, the method comprises the step of providing a semiconductor chip assembly comprising a semiconductor layer sequence with an active region configured to generate radiation. The method further comprises the step of forming a filter layer sequence on the semiconductor chip assembly wherein at least one first layer of the filter layer sequence comprises amorphous silicon. The method further comprises the step of singulating the semiconductor chip assembly with the filter layer sequence in the plurality of semiconductor chips.

The method is in particular performed in the indicated order. Consequently, the filter layer sequence is applied to the semiconductor chips prior to the singulation step so that the singulated semiconductor chips already include the filter layer sequence. Thus it is not necessary to attach a prefabricated filter to a semiconductor chip after the singulation step.

For example, the semiconductor layer sequence is epitaxially grown, for example by MOCVD or MBE on a growth substrate. The growth substrate may represent a carrier that mechanically stabilizes the semiconductor layer sequence. Alternatively, the carrier may be different from the growth substrate.

According to at least one embodiment of the method, the filter layer sequence is deposited on the semiconductor chip assembly. For example, the filter layer sequence is deposited by means of physical vapor deposition, for instance by means of sputtering, or by means of chemical vapor deposition.

According to at least one embodiment of the method, the filter layer sequence is deposited on the semiconductor chip assembly by plasma-assisted reactive magnetron sputtering. It has turned out that this method is particularly suitable in order to form a filter layer sequence with high surface density.

Furthermore developments and expediencies will be apparent from the subsequent description of the exemplary embodiments in connection with the figures.

### BRIEF DESCRIPTION OF THE DRAWINGS

In the exemplary embodiments and figures similar or similarly acting constituent parts are provided with the same reference signs. Generally only the differences with respect to the individual embodiments are described. Unless specified otherwise, the description of a part or aspect in one embodiment applies to a corresponding part or aspect in another embodiment as well.

In the figures:

FIG. 1A shows an exemplary embodiment of a filter layer sequence in a cross-sectional view;

FIG. 1B shows an exemplary embodiment of a semiconductor chip in a cross-sectional view;

FIG. 2 shows the transmission T as a function of the wavelength λ for an exemplary embodiment of a filter layer sequence at different temperatures;

FIG. 3 shows the transmission T as a function of the wavelength λ for an exemplary embodiment of a filter layer sequence at different temperatures;

FIG. 4 shows the refractive index for different materials as a function of the wavelength A;

FIG. 5 shows the transmission T as a function of the wavelength λ for an exemplary embodiment of a filter layer sequence and for a reference filter.

FIG. 6 shows the transmission T as a function of the wavelength λ for an exemplary embodiment of a filter layer sequence and for a reference filter at normal incidence and at an angle of 30°; and

FIGS. 7A to 7C show an exemplary embodiment of a method of producing a plurality of semiconductor chips by way of intermediate steps shown in schematic cross-sectional view.

The elements illustrated in the figures and their size relationships among one another are not necessarily true to scale. Rather, individual elements or layer thicknesses may be represented with an exaggerated size for the sake of better representability and for the sake of better understanding.

### DETAILED DESCRIPTION

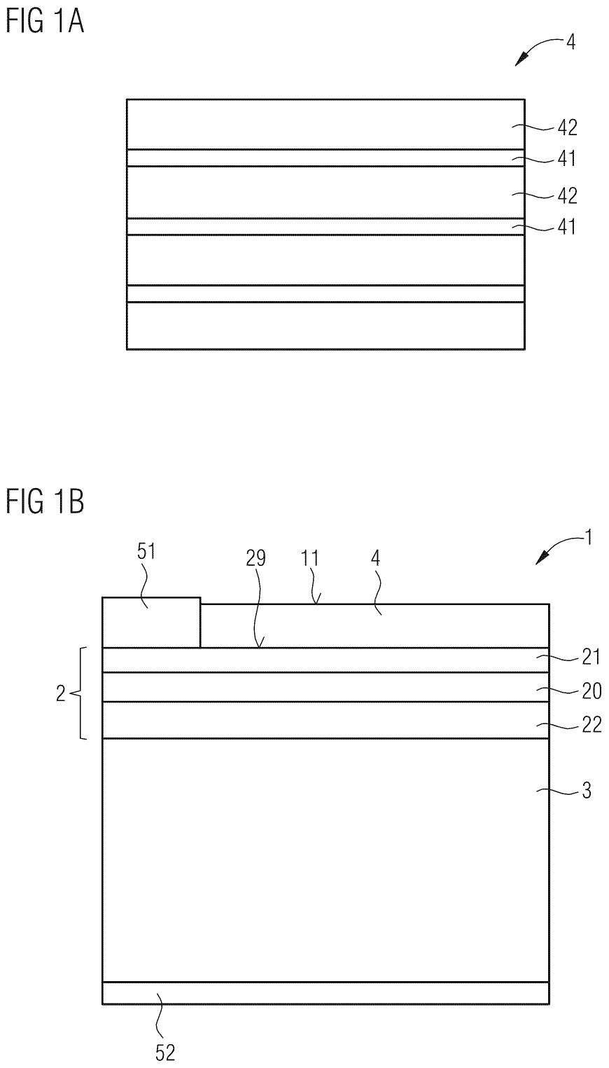

An exemplary embodiment of a filter layer sequence is illustrated in FIG. 1A. The filter layer sequence 4 comprises a plurality of first layers 41 and a plurality of second layers 42. The first layers 41 comprise amorphous silicon, in particular hydrogenated amorphous silicon. At least one first layer 41 comprising amorphous silicon is embedded by two dielectric second layers 42 and directly adjoins these two layers. The first layers 41 may differ from one another with respect to the layer thickness or the material.

The second layers 42 have a lower refractive index than the first layers 41, so that the second layers represent low refractive index layers and the first layers represent high refractive index layers of an interference filter layer sequence. For example, the refractive index of the second layers 42, in particular of all second layers 42, is at most 3. For example, the second layers 42 comprise a dielectric material such as an oxide.

For example, the combination of first layers 41 formed from hydrogenated amorphous silicon in combination with second layers 42 formed from silicon oxide has turned out to be particularly suitable. However, other materials may also apply for the first and second layers. The number of layers and the layer thicknesses and the material composition of the individual layers may be adapted to the specific requirements on the filter layer sequence using conventional design tools for interference filter structures. For example, the filter layer sequence 4 comprises at least two layers or at least five layers and/or at most 200 layers or at most 100 layers or at most 50 layers.

For example, a thickness of the first layers 41 and/or the second layers 42 is at least 1 nm or at least 5 nm or at least 10 nm and/or at most 2 μm or at most 1 μm.

A semiconductor chip 1 with such a filter layer sequence 4 is illustrated in FIG. 1B. For easier representation the individual layers of the filter layer sequence 4 are not shown in FIG. 1B.

The semiconductor chip 1 comprises a semiconductor layer sequence 2 with an active region 20 configured to generate radiation.

For example, the semiconductor layer sequence is based on a compound semiconductor material system such as an arsenide or phosphide compound semiconductor material.

The active region 20 is arranged between a first semiconductor layer 21 of a first conductivity type and a second layer 22 of a second conductivity type, so that the active region 20 is located in a pn junction. For example, the first semiconductor layer 21 is n-type and the second semiconductor layer 22 is p-type or vice versa.

The active region 20 may comprise a quantum structure.

In the context of the application, the term quantum structure comprises in particular any structure in which charge carriers can undergo a quantization of their energy states by confinement. In particular, the term quantum structure does not include any indication of the dimensionality of the quantization. It thus includes, among others, quantum wells, quantum wires, quantum rods and quantum dots and any combination of these structures.

The first semiconductor layer 21 and/or the second semiconductor layer 22 may comprise two or more sublayers.

The filter layer sequence 4 is arranged on the semiconductor layer sequence 2. The semiconductor chip 1 further comprises a first contact 51 electrically connected to the first semiconductor layer sequence 21 and a second contact 52 electrically connected to the second semiconductor layer 22. By applying an external electrical voltage between the first contact 51 and the second contact 52, charge carriers may be injected into the active region 20 from opposite sides and recombine there with emission of radiation.

The filter layer sequence 4 is arranged on the semiconductor chip 1 such that at least a portion of the first contact 51 is exposed, so that it is accessible for external electrical contacting.

The semiconductor chip 1 further comprises a carrier 3 that mechanically stabilizes the semiconductor layer sequence 2. For example, the carrier 3 is a growth substrate for the epitaxial deposition of the semiconductor layer sequence 2. However, the carrier may also be different from the growth substrate.

In the exemplary embodiment shown, the filter layer sequence 4 and the semiconductor layer sequence 2 are arranged on the same side of the carrier 3.

However, the filter layer sequence 4 and the semiconductor layer sequence 2 may also be arranged on opposite sides of the carrier 3.

Furthermore, the arrangement of the first contact 51 and the second contact 52 can be varied in wide ranges as long as charge carriers can be injected from the contacts via the first semiconductor layer 21 and the second semiconductor layer 22 respectively into the active region 20. For example the first contact 51 and the second contact 52 may be arranged on the same side of the carrier. In particular, both the first contact 51 and the second contact 52 may be located at the radiation exit side 11 of the semiconductor chip. Alternatively, both the first contact 51 and the second contact 52 may be located on the side of the semiconductor chip that faces away from the radiation exit side 11 of the semiconductor chip. For example, the semiconductor layer sequence 2 and/or the carrier 3 may comprise at least one via to obtain an electrical connection between the first contact 51 and the first semiconductor layer 21 and/or between the second contact 52 and the second semiconductor layer 22.

During fabrication of the semiconductor chip 1 the filter layer sequence 4 is deposited on the semiconductor layer sequence 2 in the exemplary embodiment shown in FIG. 1B. Thus, a connection layer such as an adhesive layer between the filter layer sequence 4 and the semiconductor layer sequence 2 is not required.

The filter layer sequence 4 is arranged on a main face 29 of the semiconductor layer sequence 2 facing away from the carrier 3. The filter layer sequence 4 forms a radiation exit side 11 of the semiconductor chip 1 so that radiation emitted by the active region has to pass through the filter layer sequence before it is emitted through the radiation exit side 11. Between the carrier 3 and the semiconductor layer sequence 2 a mirror layer, in particular a metallic mirror layer may be arranged, so that radiation emitted in the active region 20 towards the carrier 3 can be reflected at the mirror layer 3 and emitted at the radiation exit side 11.

The filter layer sequence 4 does not necessarily have to be directly deposited on the semiconductor layer sequence 2. Rather, one or more intermediate layers may be arranged between the filter layer sequence 4 and the semiconductor layer sequence 2, for example a planarization layer or a passivation layer or an electrically conductive contact structure.

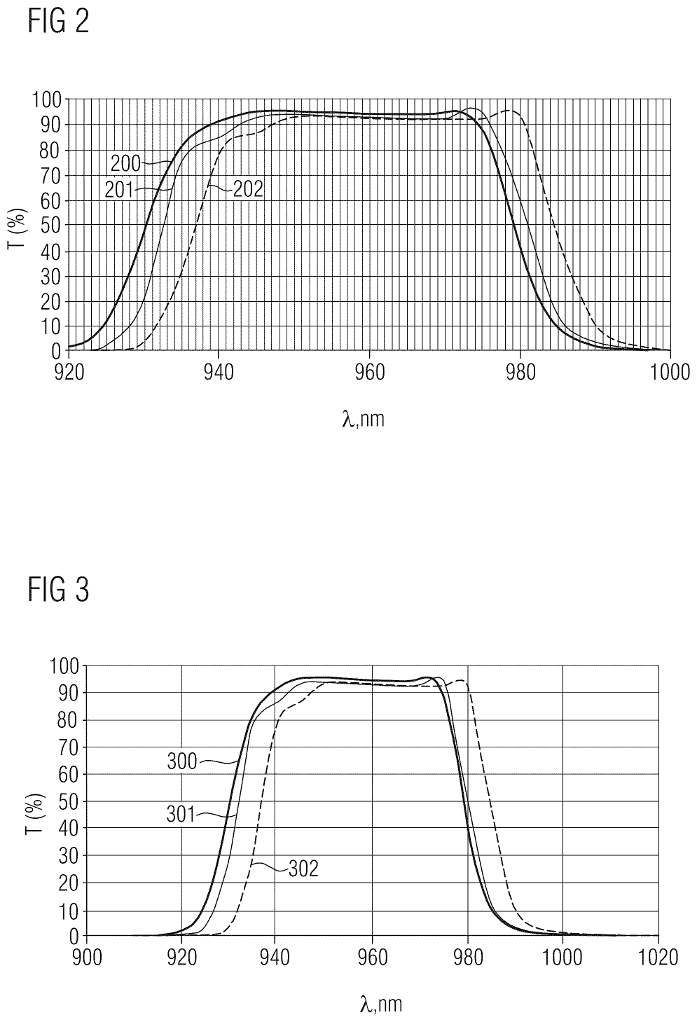

Using a filter layer sequence 4 comprising amorphous silicon, in particular at least partly hydrogenated amorphous silicon, spectral filters with a comparably small temperature dependency can be obtained. This is illustrated in FIG. 2, showing the transmission as a function of the wavelength A where curve 200 represents the transmission at room temperature, curve 201 the transmission at 100° C. and curve 202 the transmission at 175° C.

Similarly, FIG. 3 illustrates the transmission as a function of the wavelength at room temperature (curve 300), a 80° C. (curve 301) and at 175° C. (curve 302).

It turns out that the average shift between room temperature and 80° C. is 0.03 nm/K. Between 80° C. and 175° C. the average shift amounts to 0.05 nm/K. This is comparable to the typical peak wavelength shift of the emitted radiation with increasing temperature. Consequently, the fraction of the radiation emitted by the active region that passes through the filter layer sequence 4 does not significantly change with temperature.

The curves shown in FIGS. 2 and 3 refer to a bandpass filter transmitting radiation around a center wavelength of 960 nm. However, other center wavelengths or other spectral characteristics for the filter layer sequence may also be obtained by suitable modifications to the layer thicknesses and/or materials of the first layers 41 and the second layers 42. For example, the filter layer sequence may act as a highpass or lowpass filter.

The simulations are based on a filter layer sequence 4 with first layers 41 of hydrogenated amorphous silicon and second layers 42 of silicon oxide. Very step transmission edges, in particular specifically adapted to the radiation characteristics of the semiconductor chip 1, can be obtained with the described filter layer sequence 4, if desired.

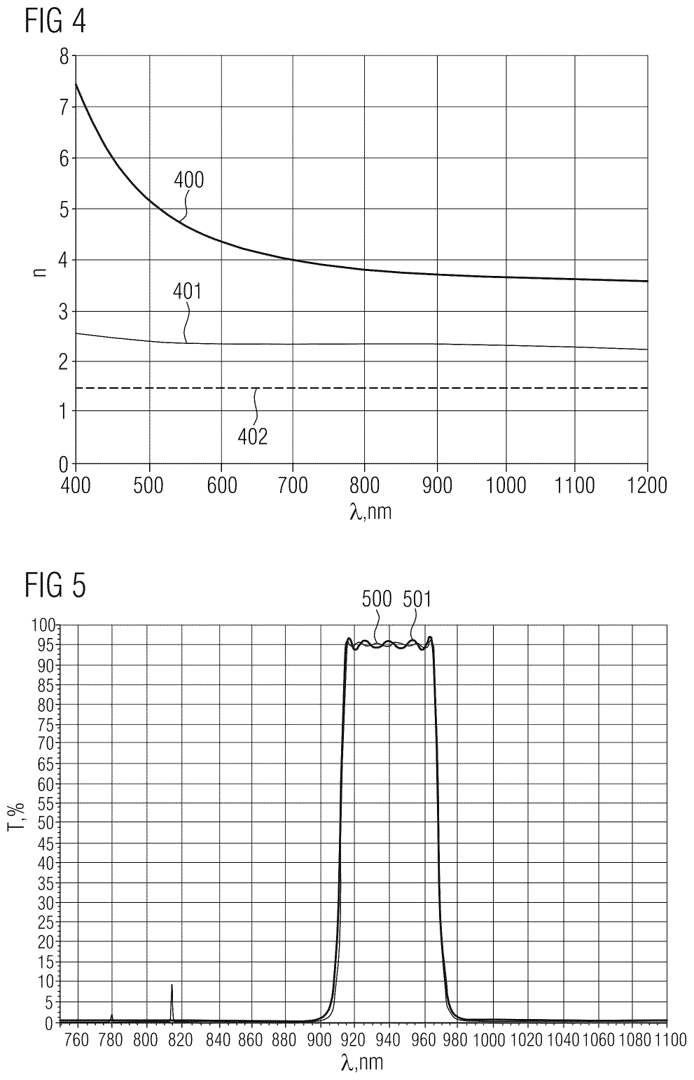

FIG. 4 illustrates the refractive index as a function of the wavelength λ for hydrogenated amorphous silicon (curve 400), niobium pentoxide (curve 401) and silicon oxide (curve 402). The figure illustrates that the refractive index of hydrogenated amorphous silicon is significantly larger than that of other conventionally used oxide materials so that a filter layer sequence 4 with an increased effective refractive index can be obtained.

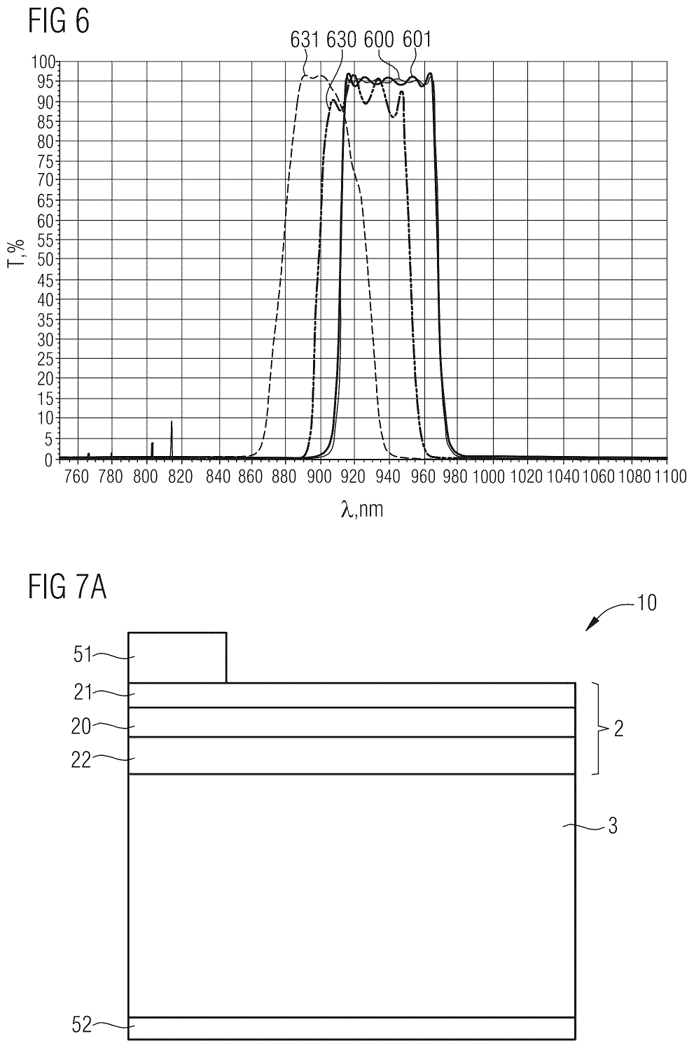

As described in connection with the subsequent FIGS. 5 and 6, this helps to reduce the wavelength shift for different angles of incidence compared to normal incidence.

Curve 500, shown in FIG. 5, refers to a filter layer sequence 4 using hydrogenated amorphous silicon as first layers 41 and silicon oxide as second layers 42 with a total number of 25 layers and a total thickness of 3.7 μm. For comparison, curve 501 shows a conventional filter using Nb₂O₅ as first layers and SiO₂ as second layers. The curves illustrate that at normal incidence the performance of the two bandpass filters with a center wavelength at 940 nm is similar. However, the conventional filter belonging to curve 501 is more complex to produce as it requires 50 layers with an overall physical thickness of 6 μm.

Curves 600 and 601 shown in FIG. 6 correspond to curves 500 and 501 of FIG. 5 respectively. Curve 630 refers to the same filter layer sequence as curve 600 but relates to an angle of incidence of 30°. Accordingly, curve 631 relates to the same structure as curve 601 but at an angle of incidence of 30° as well.

FIG. 6 clearly illustrates that the angular shift of the transmission for exemplary embodiment using hydrogenated amorphous silicon as first layers 41 is much smaller than for the reference sample using Nb₂O₅ as first layers 41 instead.

Consequently, a semiconductor chip 1 with such a filter layer sequence 4 is able to provide stable angular radiation characteristics with a comparably small temperature shift. In other words, the change in the power of the emitted radiation within the field of view relevant for the application of the semiconductor chip 1 may be reduced.

For example, such a semiconductor chip is particularly suited for applications where large temperature ranges need to be covered during operation, for example in outdoor or automotive applications.

Furthermore, undesired red glow of an LED emitting in the near infrared spectral range can be reliably suppressed by the filter layer sequence 4 so that an additional filter arranged downstream of the semiconductor chip 1 can be dispensed with.

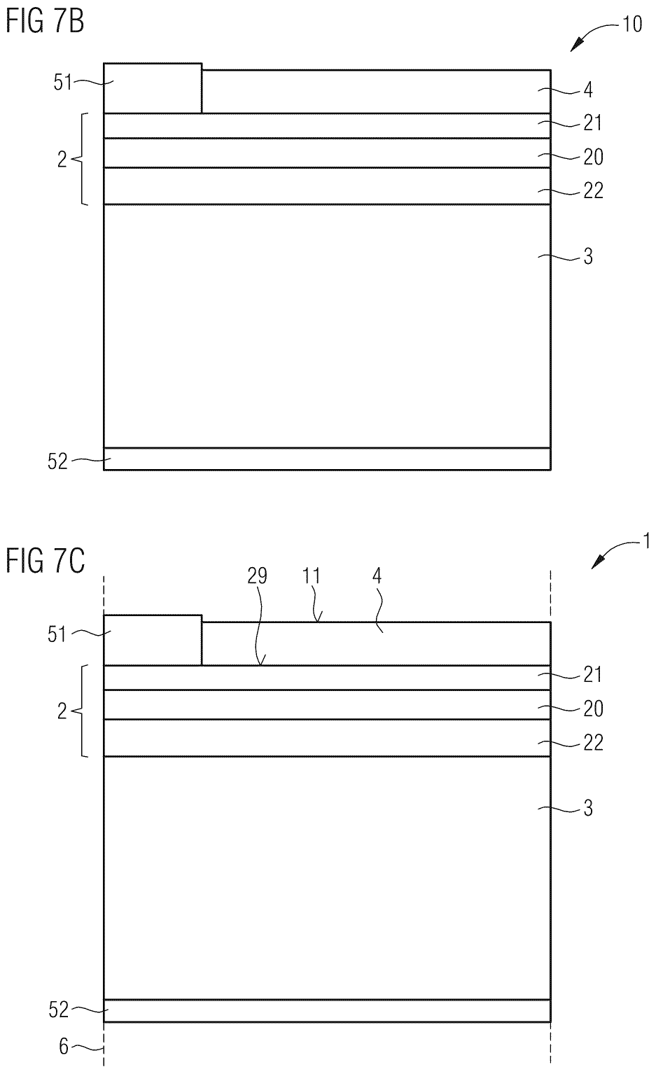

A method of producing such semiconductor chips is illustrated using intermediate steps shown in FIGS. 7A to 7C.

In the exemplary embodiment shown, semiconductor chips embodied as described in connection with FIG. 1B are produced. However, the method can also be used for the production of other semiconductor chip designs.

As illustrated in FIG. 7A, a semiconductor chip assembly 10 comprising a semiconductor layer sequence 2 with an active region 20 configured to generate radiation is provided. For the sake of easier representation only a part of the semiconductor chip assembly 10 resulting in one finished semiconductor chip 1 is shown. The semiconductor layer sequence 2 is arranged on a carrier 3, which may be a growth substrate of the semiconductor layer sequence 2 or a replacement carrier connected to the semiconductor layer sequence 2 using a wafer bonding process, for instance.

As illustrated in FIG. 7B, a filter layer sequence 4 is formed on the semiconductor chip assembly 10 wherein at least one first layer 41 of the filter layer sequence 4 comprises amorphous silicon.

The filter layer sequence 4 is deposited on the semiconductor chip assembly 10, for example by plasma-assisted reactive magnetron sputtering. However, another deposition technique may also apply.

Subsequently the semiconductor chip assembly is singulated along singulation lines 6 (FIG. 7C) in order to form the individual semiconductor chips. This can be done mechanically, for instance by sawing, chemically, for instance by etching and/or using coherent radiation.

Consequently the semiconductor chips 1 obtained after singulation already contain the filter layer sequence 4. Side faces of the carrier 3 may exhibit characteristic traces of the singulation processes such as sawing traces.

The described method allows to produce semiconductor chips 1 with superior emission characteristics in a simple and reliable manner.

The present disclosure described here is not restricted by the description given with reference to the exemplary embodiments. Rather, the present disclosure encompasses a novel feature or any combination of features including in particular any combination of features in the claims, even if this feature or this combination is not itself explicitly indicated in the claims or exemplary embodiments.

### REFERENCES

1 semiconductor chip
10 semiconductor chip assembly
11 radiation exit side
2 semiconductor layer sequence
20 active region
21 first semiconductor layer
22 second semiconductor layer
29 main face
3 carrier
4 filter layer sequence
51 first contact
52 second contact
6 singulation line
200, 201, 202 curve
300, 301, 302 curve
400, 401, 402 curve
500, 501, 502 curve
600, 601, 630, 631 curve

What is claimed is:

1. A semiconductor chip comprising:
a semiconductor layer sequence with an active region configured to generate incoherent radiation; and
a filter layer sequence, wherein at least one first layer of the filter layer sequence comprises amorphous silicon.

2. The semiconductor chip according to claim 1,
wherein the amorphous silicon is hydrogenated at least in regions.

3. The semiconductor chip according claim 1,
wherein the filter layer sequence (4) comprises at least one second layer (42) comprising a dielectric material.

4. The semiconductor chip according to claim 3,
wherein a refractive index of the at least one second layer is smaller than a refractive index of the at least one first layer.

5. The semiconductor chip according to claim 3,
wherein a refractive index of the at least one second layer is at most 3.

6. The semiconductor chip according to claim 1,
wherein the active region is configured to emit radiation with a peak wavelength in the near infrared range.

7. The semiconductor chip according to claim 1,
wherein the filter layer sequence is configured to block radiation in the visible range.

8. The semiconductor chip according to claim 1,
wherein the filter layer sequence is configured as an angle-selective filter.

9. The semiconductor chip according to claim 1,
wherein the filter layer sequence is configured as a bandpass filter.

10. The semiconductor chip according to claim 1,
wherein the filter layer sequence is deposited on the semiconductor layer sequence.

11. A method of producing a plurality of semiconductor chips comprising:
a) providing a semiconductor chip assembly comprising a semiconductor layer sequence with an active region configured to generate radiation;
b) forming a filter layer sequence on the semiconductor chip assembly wherein at least one first layer of the filter layer sequence comprises amorphous silicon; and
c) singulating the semiconductor chip assembly with the filter layer sequence in the plurality of semiconductor chips.

12. The method according to claim 11,
wherein forming the filter layer sequence includes depositing the filter layer sequence on the semiconductor chip assembly.

13. The method according to claim 11,
wherein the filter layer sequence is deposited on the semiconductor chip assembly in step b) by plasma-assisted reactive magnetron sputtering.

14. (canceled)

15. A semiconductor chip comprising:
a semiconductor layer sequence with an active region configured to generate incoherent radiation; and
a filter layer sequence, wherein at least one first layer of the filter layer sequence comprises amorphous silicon, and wherein the filter layer sequence is deposited on the semiconductor layer sequence.
